(19) United States
(12) Patent Application Publication
(10) Pub. No.: US 2017/0115329 A1
(43) Pub. Date: Apr. 27, 2017

(54) SCALABLE AVERAGE CURRENT SENSOR SYSTEM

(71) Applicant: MEMSIC, INC., Andover, MA (US)

(72) Inventors: George Schuellein, Narragansett, RI (US); Bin Liu, Gibsonia, PA (US); Alexander Dribinsky, Naperville, IL (US)

(21) Appl. No.: 15/288,174

(22) Filed: Oct. 7, 2016

Related U.S. Application Data
(60) Provisional application No. 62/245,032, filed on Oct. 22, 2015.

(51) Int. Cl. G01R 15/20; G01R 19/25; G01R 19/00

(52) U.S. Cl. CPC G01R 15/205; G01R 19/0092; G01R 19/2506

(57) ABSTRACT

A current sensor configured to be employed in an array of current sensors and an array of parallel connected current sensors is disclosed. In one embodiment the current sensors comprise integrated circuit current sensors and a plurality of the current sensors are connected in parallel in a number that is selected to at least accommodate the maximum magnitude of a current to be monitored. When configured in parallel as an array of sensors, at least one of the current sensors of the array of current sensors provides an output signal that represents an average of the currents measured by the plurality of current sensors in the array.

### CROSS REFERENCE TO RELATED APPLICATIONS

This application claims priority of U.S. provisional application 62/245,032 filed Oct. 22, 2015 and titled Scalable Average Current Sensor System.

### BACKGROUND OF THE INVENTION

Current sensors are provided as an integral part of many electronic systems and employ different methods for the current sensing process. Generally, a current sensor is a device that provides a current path from a current input to a current output and that generates an output signal that is representative of the magnitude of the current flowing through the current path. Common current sensing methods include resistive shunt measurements, measurements based on the direct current resistance of a magnetic element, transformer based measurements, MOSFET RDS on or ratiometric measurements, Hall Effect measurements and Magneto Resistive measurement techniques. Each method has various advantages and disadvantages.

Resistive shunt sensors are one of the simplest techniques and potentially most accurate methods for sensing current. However, when measuring currents greater than approximately 10 amps, I²R ohmic power losses become significant and limit the application of this approach. Additionally, the resistive shunt technique is not galvanic plate isolated and thus becomes inappropriate for systems sensing voltages above 24 V and certainly above 60 V which is considered the maximum safe voltage that a human can directly touch. A resistive shunt sensor also has a limited dynamic range. A shunt resistor has to be scaled to give the right amount of voltage drop to be amplified and measured but not so high a resistance as too cause too large a voltage drop.

Hall Effect sensors are available in several configurations for the measurement of higher currents in the range of 50-20,000 amps. These configurations generally require that the current to be sensed pass through a large magnetic element. Transformer type current sensors employed in the sensing of currents in excess of 200 amps tend to be bulky devices. A conductor carrying the current to be measured typically passes through an opening in the transformer type current sensor which in turn is electrically coupled to an associated integrated circuit for processing. The transformer type current sensor and the integrated circuit are separate devices which are often mounted to a common substrate, such as a printed circuit board. Consequently, the end user must provide an external magnetic sensor and conductor associated with the sensor that is interconnected with the integrated circuit.

It is often desirable to sense currents which are greater than the maximum current rating of an integrated circuit sensor. This can be done by splitting the total current into two or more paths to and assuring that the current measured on each path with an integrated circuit does not exceed the maximum current rating for the respective device. However, due to practical considerations, it is difficult to know the current divide ratio and different currents may flow in different current paths. This approach therefore can lead to reduced accuracy or require a post-assembly calibration.

One current sensor that is capable of parallel interconnection for high current measurement is available from Texas Instruments™ under model number INA250. Each INA250 current sensor includes a shunt resistor. A portion of the current to be sensed passes through each of the shunt resistors when the INA250 devices are used in parallel. In this device, the resulting current that is sensed is the sum of the currents sensed by each of the current sensors and required bias and output voltages disadvantageously increase with an increasing number of parallel connected sensors, necessitating the addition of larger power voltages as the number of current sensors increase.

It would therefore be desirable to have a current sensor that was fabricated as a small integrated circuit (IC) that allowed the IC based current sensor to be used in high current measurement applications. Additionally, it would be desirable to have a current sensor that was scalable so as to permit the IC based current sensor to meet a wide range of application requirements, including high current measurement requirements, while avoiding the need to provide increasing bias power supplies and output voltages with an increasing number of current sensors.

### BRIEF SUMMARY OF THE INVENTION

In accordance with the present invention an IC based current sensor is disclosed. The disclosed current sensor is configured to permit multiple IC based current sensors to be connected in parallel as an array of current sensors. When configured as a plurality of current sensor interconnected in parallel as an array, a portion of the current to be measured passes through each one of the plurality of current sensors in the array. The maximum permissible current specification for the array is thus approximately the maximum current specification for each current sensor multiplied by the number of current sensors in the array. The array of current sensors provides as an output a signal that represents the average of the currents sensed by the plurality of current sensors in the array. Since any number of the IC based current sensors may be connected in parallel, a current sensing solution is provided that is scalable to satisfy any current sensing requirement.

### BRIEF DESCRIPTION OF THE SEVERAL VIEWS OF THE DRAWINGS

The invention will be more fully understood by reference to the following Detailed Description of the Invention in conjunction with the Drawings of which:

FIG. 1 is a simplified schematic diagram of a current sensor in accordance with the present invention that is configured to permit parallel connection of the current sensor with one or more like current sensors;

FIG. 2 is a simplified schematic diagram depicting a plurality of parallel interconnected current sensors in accordance with the present invention; and

FIG. 3 is a schematic diagram of the current sensor of FIG. 1 that includes circuitry for offset and gain adjustments.

### DETAILED DESCRIPTION OF THE INVENTION

U.S. provisional application 62/245,032 filed Oct. 22, 2015 and titled Scalable Average Current Sensor System is hereby incorporated herein by reference it its entirety.

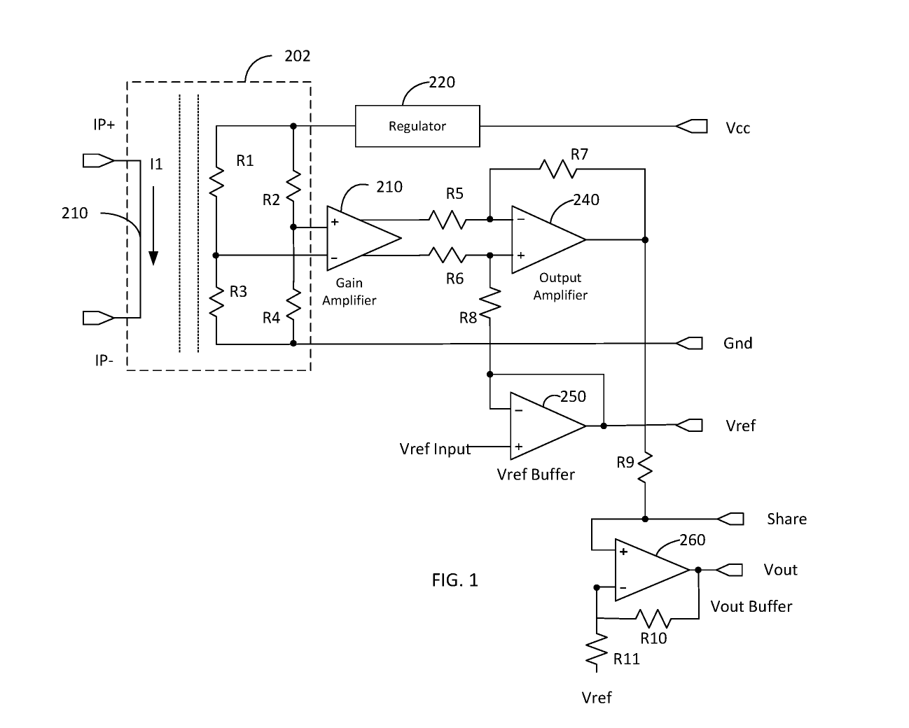

A scalable IC based current sensor 200 in accordance with the present invention and an array of such sensors interconnected in parallel are depicted in FIGS. 1-3.

The disclosed current sensor may be provided as a fully integrated bi-directional current sensor that deliver both high accuracy and high bandwidth. In one embodiment Anisotropic Magneto Resistive (AMR) current sensing is employed which provides low noise, excellent linearity and repeatability. Any other suitable current sensing technology may also be utilized.

A fully isolated current path is provided by a low resistance copper conductor integrated into the package making it suitable for both high-side and low side bi-directional current sensing. The current sensor has a high bandwidth which makes it suitable for feedback loops in motor control and power supply applications.

Referring to FIG. 1, the current sensor includes a current sensing element 202 which, in the illustrated embodiment is an Anisotropic Magneto Resistive (AMR) sensor. While the illustrated sensing element 202 is depicted as an AMR sensing element, the current sensing element may a shunt resistive element, DC Resistance (DCR), a Hall Effect sensor, a transformer, or any other suitable current sensing element. The current sensor 200 provides an output signal that is representative of the current I₁ traversing a current path 210 between IP+ and IP−. The output of the current sensing element 202 is coupled to the input of a gain stage amplifier 230 which in turn is coupled to an output stage amplifier 240. The output stage gain is determined by resistors R₅, R₆, R₇ and R₈. A unity gain voltage reference buffer 250 is provided with a reference input (V_{ref} input) that provides a bias reference for the output stage amplifier 240. The output from the output stage amplifier 240 is a voltage signal that represents and is proportional to the current I₁ traversing the current path 210. The output stage amplifier 240 output is coupled to a SHARE connection through a resistor R₉ and the SHARE connection is connected to an output buffer 260 input. In the illustrated embodiment, the output buffer is shown as an amplifier 260 that provides an output signal Vₒᵤₜ. The gain of the amplifier 260 is determined by the resistors R₁₀ and R₁₁. The presently described circuit may be fabricated using discrete electronic components, as an integrated circuit or, as a combination of discrete components and one or more integrated circuit components. The SHARE connection is an external connection when the current sensor 200 is fabricated using one or more integrated circuits that include the relevant circuitry to the permit the SHARE connections of multiple current sensors 200 to be bussed together and thus electrically interconnected one to the other.

More specifically, the AMR sensor 202 monitors the magnetic field generated by the current I₁ flowing through a U shaped current pathways from IP+ to IP− in an integrated circuit package lead frame. The AMR sensor 202 produces a voltage proportional to the magnetic field created by the positive or negative current in the IP+ to IP− current loop 210 while rejecting external magnetic interference. The current sensor 202 output voltage is coupled to a differential amplifier 230 whose gain is temperature compensated. The differential amplifier 230 output is in turn coupled to an output stage an amplifier 240. The output stage amplifier 240 produces an output voltage that is representative of the current passing through the IP+ to IP− pathway 210. To provide both positive and negative current data, the Vₒᵤₜoutput pin is referenced to the V_{ref} output pin. The voltage on the V_{ref} output is typically about one half of the full scale positive and negative range of the Vₒᵤₜ output signal. With no current flowing through the IP+/IP− pins, the voltage on the Vₒᵤₜ output will typically equal the voltage on the V_{ref} output. Positive IP+/IP− current causes the voltage on Vₒᵤₜ to increase relative to V_{ref} while negative IP+/IP− current will cause it to decrease.

The current sensor 200 may optionally include a voltage regulator 220 to provide a regulated bias voltage to the current sensing element 202 and to provide fixed gain from the sensor resistors R₁-R₄. When a voltage regulator 220 is employed, the sensor resistors R₁-R₄ are biased with a fixed voltage so as to immunize the current sensing circuitry 202 from changes in the V_{cc} supply voltage.

When the voltage regulator 220 is omitted, the sensor resistors R₁-R₄ are biased to the Vcc supply voltage and produce a differential voltage that is ratiometric to V. This configuration is suited to applications where analog-to-digital converter (A-to-D) circuitry receiving the current sensor output signal from Vₒᵤₜ are biased by, and ratiometric to, the same supply voltage as the current sensor. The ratiometric configuration provides increased gain and enhanced supply rejection compared to the embodiment that includes the regulator 220.

Power is provided to the current sensor 200 between V_{cc} and Gnd.

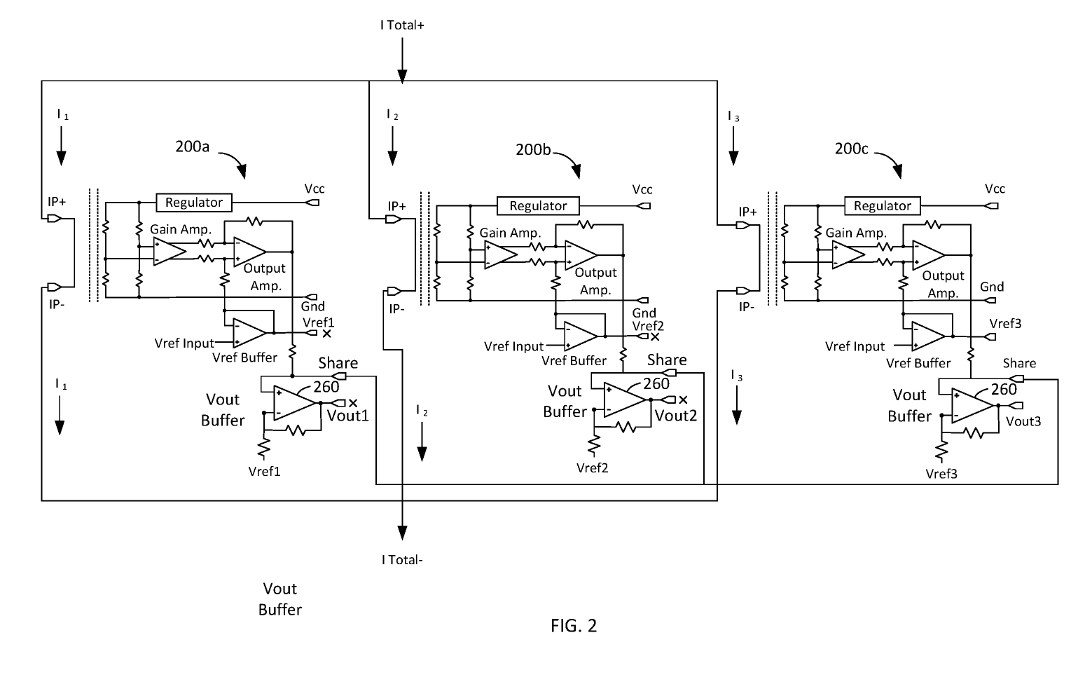

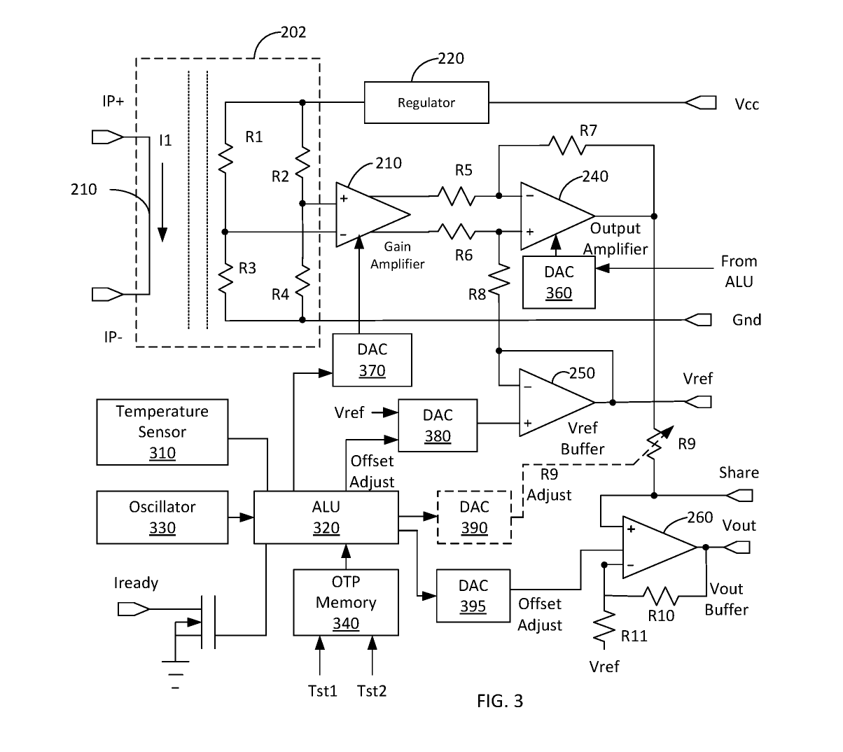

In FIGS. 1 and 2, input signals for offset and gain adjustments that may be provided for purposes of temperature compensation or component variations have been omitted to more clearly describe the operation of the current sensor 200 individually and when employed in an array. Such components, however, are illustrated and discussed below in connection with FIG. 3.

When the current sensor 200 is used as a single sensor, the output signal Vₒᵤₜ is a voltage output that is representative of the current I₁ through the current path 210 of the current sensing element 202. Additionally, when the current sensor 200 is used singularly, the maximum current that can be accommodated and measured by the device is limited to the maximum current rating of the respective sensor 200.

As illustrated in FIG. 2, current sensors 200 may be interconnected and arrayed in parallel to extend the measurement capability of current sensor fabricated as an integrated circuit to high current applications.

Referring to illustrative FIG. 2, three current sensors 200a-200c are connected in parallel with the SHARE connections of the three current sensors electrically connected to one another. A total current I_{Total} which is the sum of currents I₁, I₂ and I₃, passes through the current sensor array, with a first portion of the total current, I₁, passing through a first current sensor 200a, a second portion of the total current, I₂, passing through a second current sensor 200b and a third portion of the total current, I₃, passing through a third current sensor 200c. While three current sensors are illustrated in the parallel interconnected array depicted FIG. 3, any number of current sensors 200 may be connected in parallel via the SHARE connection. It is further noted that all IP+ connections of current sensors are bussed together and all IP− connections of current sensors are bussed together so that portions of the total current I_{Total} pass through each of the current sensors in the array.

Since it is difficult to fabricate multiple current splitting paths so that the currents passing through each individual path are all exactly equal, the currents I₁, I₂ and I₃ carried by the current pathways of the respective sensors may be mismatched. Thus, the output voltages from the output amplifiers 240 (See FIG. 1) in the respective current sensors may differ. By bussing the SHARE connections of the current sensors together, and setting each resistor R₉ to be the same value within an acceptable and defined tolerance, the voltage on the SHARE terminal represents the average of the voltages on the output of the output stage amplifiers 240 of the various current sensors and thus, the average of the currents flowing through the current pathways of the three current sensors. Since the number of current splitting paths and the number of sensors are known in advance, the average of the currents conveys the same information as the total current. More specifically, the total current is the average current times the number of current splitting paths. Additionally, while ideally, the value of the resistors are equal, it should be recognized, that, in practice, it is extremely difficult to perfectly match any two electrical components. The value of the resistors R₉ are equal within a defined tolerance and, in this context, are substantially equal. The resistor R₉ may be preselected or trimmed during production to a desired value within a specified tolerance. For example, the resistor R₉ may be trimmed during fabrication of an integrated circuit to within 1% of the specified value. Alternatively, the resistor R₉ may be provided as a controllable resistance which may be adjusted to achieve a desired value as illustrated in FIG. 3.

The SHARE terminal is connected to the input of the Vₒᵤₜ Buffer. The Vₒᵤₜ Buffer provides a voltage output corresponding to the average of the voltage outputs of the Output Amplifiers 240 of the current sensors. An output from one of the Vₒᵤₜ Buffers is employed, as illustrated in FIG. 2, although each of the output buffers in the illustrated embodiment produces the same output voltage. The outputs from the other Vₒᵤₜ. Buffers are not used as illustrated in FIG. 2 by an “X”.

The array of current sensors thus serves as a current sensor having a theoretical maximum amperage specification equal to the number of current sensors in the array times the maximum amperage specification of each of the current sensors. In practice, since the currents may not split evenly among multiple current paths, the actual maximum amperage specification will be less than the theoretical maximum amperage specification since no current path may exceed the maximum current rating for the respective current sensor and some current paths may carry less than the maximum current for which the respective sensors are rated. The disclosed system provides several advantages over known prior art systems using parallel connected current sensors to accommodate current measurements in excess of the maximum current specification of a single current sensor.

When a current sensor as described above is fabricated as an integrated circuit, a current sensing solution can be provided that is much smaller in size when compared to existing solutions used for sensing 50 amps or greater. Additionally, by sensing the average current sensed by the array of sensors, an accurate current measurement may be obtained even if the total current I_{Total} being measured is not divided equally among all of the individual sensors in the sensor array. Furthermore, since any number of current sensors may be connected in parallel, the array of current sensors formed upon interconnection can accommodate any level of current. Additionally, unlike known systems which require voltage supplies having higher voltages as the number of stages increase, the presently disclosed system employs a single Vcc supply voltage irrespective of the number of current sensors employed in the array. Thus, the need for multiple power supplies of different voltages is avoided. Lastly, thermal management is simplified since current sensors may be physically spread out to minimize local heating.

FIG. 3 illustrates the current sensor of FIG. 1 but includes components for providing offset and gain adjustments for bias and temperature compensation. More specifically, as illustrated in FIG. 3, the current sensor 200 also includes a temperature sensor 310, an arithmetic logic unit (ALU) 320 which is interfaced to a processor (not shown) and an oscillator 330 providing a clock for the ALU 320. The ALU 320 includes digital outputs that are coupled to Digital to Analog Converters (DACs) 360, 370, 380, 390, 395 which in turn have analog outputs coupled to the Output State Amplifier 240, Gain Stage Amplifier 210, V_{ref} Buffer 250, optionally to R9 if R9 is adjustable and to the Vₒᵤₜ Buffer 260 to permit gain, offset or value adjustments to the respective components, as applicable. A control signal I_{Ready} is provided as an output from the ALU that is coupled to an input of the processor to permit the processor to detect when the ALU has powered up after a power up sequence.

A digital compensation scheme allows for compensation due to variations of sensor sensitivity and offset with temperature. Both the offset and gain of the entire signal path are adjustable using the digital to analog converters (DACs). The high resolution (16 bit) digital temperature sensor 310 measures the temperature of the sensor 200. The arithmetic logic unit (ALU) 320 calculates trim codes for the offset and gain of the amplifiers 230, 240, 250, 260 based on the temperature sensor 310 inputs. When there is a change in these codes there will be a step at the output that provides a correction in gain or offset should such be necessary. The DACs have a small step size to provide a fine adjustment capability in sensor output voltage. In one embodiment, the temperature readings are collected and output codes are re-calculated at a rate of approximately 2 kHz although any suitable rate may be employed. The control codes do not change by more than 1 LSB at a time which guarantees a small step at the outputs. Filtering is used on the temperature sensor 310 output to minimize noise on the temperature sensor 310 output signal. Initial accuracy may be pre-programmed into a one-time programmable (OTP) memory through the two TST pins.

While the disclosed embodiment utilizes digital techniques for controlling temperature compensation and offset adjustments, it will be recognized by those of ordinary skill in the art that analog techniques for such control may alternatively be employed.

While the illustrated current sensor 200 provides an analog output, it should be recognized that an analog to digital converter (A-to-D) may be employed to convert the analog output to a digital output representative of the total current I_{Total}.

As described above, the disclosed current sensor and method of use permit like current sensors to be interconnected in parallel in a scalable manner to provide for the measure of large currents. When interconnected in parallel, the system provides an output that is the average of the currents flowing through the respective interconnected current sensors. It will be appreciated by those of ordinary skill in the art that variations of and modifications to the above-described current sensor and method may be made without departing from the inventive concepts disclosed herein.

Accordingly, the invention should not be viewed as limited except by the scope and spirit of the appended claims.

What is claimed is:

1. A current sensing system for generating an output signal representative of a total current flowing through the current sensing system, the current sensing system comprising:
a plurality of like current sensors, each current sensor including:
a current pathway extending through the respective current sensor and carrying a portion of the total current,
current sensing circuitry having an output for generating a first signal representing the portion of the total current flowing through the respective current pathway; and
an output stage coupled to the output of the current sensing circuitry, the output stage including an electrical contact;
wherein:
the current pathways of the plurality of current sensors are connected in parallel so that the total current equals the sum of the portions of the total current flowing through the plurality of current sensors;
the electrical contact of each output stage is electrically interconnected to the electrical contact of each other output stage of the plurality of current sensors; and
the output stages of the plurality of current sensors are configured so as to produce an output stage output signal at least one of the output stages of the plurality of current sensors that corresponds to an average of the portions of the total current flowing through the plurality of current pathways.

2. The current sensing system of claim 1 wherein each one of the current sensors comprises an integrated circuit current sensor.

3. The current sensing system of claim 1 wherein the current sensing circuitry of each one of the plurality of current sensors includes at least one Anisotropic Magneto Restrictive current sensing component for generating the first current signal representative of the portion of the total current flowing through the respective current pathway.

4. The current sensing system of claim 1 wherein the output stage of each current sensor includes:
an output stage amplifier having an output stage amplifier input and an output stage amplifier output, and wherein the first current signal is coupled to the output stage amplifier input of the respective current sensor;
an output buffer having an output buffer input and an output buffer output;
a resistor coupled between the output of the output stage amplifier and the output buffer input, wherein the resistance the resistors in each of the current sensors are substantially the same; and
wherein the electrical contact is coupled to the input of the output buffer.

5. A current sensor comprising:
a current path extending between first and second electrical contacts for carrying an electrical current through the current sensor;
current measurement circuitry including an output representative of the electrical current flowing through the current path;
an output buffer having an output buffer input and an output buffer output;
a resistor having first and second ends, the first end electrically coupled to the output representative of the electrical current flowing through the current path and the second end coupled to the output buffer input; and
a third electrical contact coupled to the second end of the resistor and the input to the output buffer.

6. The current sensor of claim 5 wherein the current sensor comprises an integrated circuit current sensor, the first, second and third electrical contacts comprise first, second and third external contacts of the integrated circuit.

7. The current sensor of claim 5 wherein the current sensor includes an Anisotropic Magneto Restrictive current sensor for generating a first signal representative of the electrical current flowing through the current pathway.

8. A current sensing system including a plurality of current sensors as recited in claim 1 wherein:
the first electrical contact of each one of the plurality of current sensors is electrically interconnected to each of the first electrical contacts of each other one of the plurality of current sensors provide a first electrical node;
the second electrical contacts of each one of the plurality of current sensors are electrically interconnected to provide a second electrical node;
the third electrical contacts of each one of the plurality of current sensors are electrically interconnected to provide a third electrical node; and
in response to the application of a total current that flows between the first and second electrical nodes, the total current divides between or among the plurality of current sensors, as applicable, and the output buffer output is operative to provide an output signal that is representative of the average of the currents flowing through the plurality of current sensors.

9. The current sensing system of claim 8 wherein the resistor in each one of the plurality of current sensors has substantially the same resistance value.

10. A current sensing system for generating an output signal proportional to a total electrical current, the current sensing system comprising:
a plurality of current sensors, each current sensor including:
a current pathway extending between first and second electrical contacts for carrying a portion of the total current through the respective current sensor,
current measurement circuitry including an output representative of the portion of the total electrical current flowing through the current pathway of the respective current sensor;
an output buffer having an output buffer input and an output buffer output;
a resistor having first and second ends, the first end being electrically coupled to the current measurement circuitry output and the second end coupled to the output buffer input, and
a third electrical contact coupled to the second end of the resistor and the output buffer input;
wherein:
the first electrical contact of each one of the plurality of current sensors is electrically interconnected with the first electrical contact of each other one of the plurality of current sensors and the second electrical contact of each one of the plurality of current sensors is electrically interconnected with the second electrical contact of each other one of the plurality of current sensors so that a portion of the total current flows through a current pathway of each one of the plurality of current sensors and the total of the portions of the total current flowing through the current pathways of the plurality of current sensors equals the total current; and
the third electrical contact of each one of the plurality of current sensors is electrically interconnected to the third electrical contact of each other one of the plurality of current sensors; and
a resistance value of the resistor of each one of the plurality of current sensors is substantially the same as the resistance value of the resistor of each other one of the plurality of current sensors; and
wherein the output buffer output is a signal that corresponds to the average of the portions of the current flowing through the current pathways of the plurality of current sensors.

11. A method for sensing a total current comprising:
connecting a plurality of current sensors in parallel such that a portion of the total current flows through a current pathway in each one of the plurality of current sensors;
measuring the portion of the total current flowing through the current pathway in each one of the plurality of current sensors;
generating a plurality of first signals representative of the portion of current flowing through the current pathway of each one of the plurality of current sensors;
generating a second signal representative of the average of the currents flowing through the current pathways of the plurality of current sensors from the output signals representative of the current flowing through the current pathways of each one of the plurality of current sensors.

12. The method of claim 11 where the generating step comprises the step of coupling each of the plurality of first signals to a common node via a plurality of corresponding resistors of substantially the same resistance value.

13. The method of claim 12 further including the step of adjusting a resistance value of at least some of the plurality of resistors such that each one of the plurality of resistors has the same resistance value.
